(19) United States
(12) Patent Application Publication
(10) Pub. No.: US 2025/0176311 A1
(43) Pub. Date: May 29, 2025

(54) MICRO LED ELEMENT, MICRO LED DISPLAY PANEL AND DISPLAY DEVICE

(71) Applicant: JADE BIRD DISPLAY (SHANGHAI) LIMITED, SHANGHAI (CN)

(72) Inventors: Weisin TAN, Shanghai (CN); Zhichen GU, Shanghai (CN); Qunchao XU, Shanghai (CN)

(21) Appl. No.: 18/954,542

(22) Filed: Nov. 21, 2024

(30) Foreign Application Priority Data
Nov. 24, 2023 (WO) PCT/CN2023/133967

(51) Int. Cl. H01L 33/00; H01L 25/075; H01L 33/46; H01L 33/62

(52) U.S. Cl. CPC H10H 20/052; H01L 25/0753; H10H 20/841; H10H 20/857

(57) ABSTRACT

A micro LED display panel includes a mesa including a first semiconductor layer, a light emitting layer, and a second semiconductor layer that are stacked from top down; a passivation layer formed on a sidewall surface of the mesa; and a Schottky metal layer disposed adjacent to the passivation layer, wherein the Schottky metal layer creates a depletion region at least in the light emitting layer.

### CROSS-REFERENCE TO RELATED APPLICATIONS

This disclosure claims the benefits of priority to PCT Application No. PCT/CN2023/133967, filed on Nov. 24, 2023, which is incorporated herein by reference in its entirety.

### TECHNICAL FIELD

The present disclosure generally relates to micro display technology, and more particularly, to a micro light emitting diode (LED) element, a micro LED display panel, and a display device.

### BACKGROUND

Inorganic micro pixel light emitting diodes, also referred to as micro light emitting diodes, micro LEDs, or u-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) back panel. Each pixel of the micro LED display panel is formed by one or more micro LEDs. The micro LED display panel can be a mono-color or multi-color panel. In particular, for a multi-color LED panel, each pixel may further include multiple sub-pixels formed by multiple micro LEDs, each of which corresponds to a different color. For example, three micro LEDs respectively corresponding to red, green, and blue colors may be superimposed to form one pixel. The different colors can be mixed to produce a broad array of colors.

Nowadays, the size of a mesa in a micro LED may be less than 5 μm, and mesas are usually formed by etching. Etching in such a small size may damage the mesa edges of micro LEDs. Such damage may cause the micro LEDs to suffer from low efficiency due to carriers' non-radiative recombination on the mesa edges of micro LEDs. This non-radiative recombination does not generate light for displaying but only useless heat.

Therefore, there is a need for improving the lighting efficiency of micro LEDs.

### SUMMARY OF THE DISCLOSURE

Some embodiments of the present disclosure provide a micro LED element. The micro LED element includes a mesa including a first semiconductor layer, a light emitting layer, and a second semiconductor layer that are stacked from top down; a passivation layer formed on a sidewall surface of the mesa; and a Schottky metal layer disposed adjacent to the passivation layer, wherein the Schottky metal layer creates a depletion region at least in the light emitting layer.

Some embodiments of the present disclosure provide a micro LED display panel. The micro LED display panel includes an integrated circuit (IC) backplane; and a plurality of micro LED elements according to any of micro LED element described above, wherein each of the plurality of micro LED elements is disposed on a top surface of the IC backplane.

Some embodiments of the present disclosure provide a micro LED display panel. The micro LED display panel includes an IC backplane; a plurality of micro LED elements disposed on a top surface of the IC backplane, wherein each of the plurality of micro LED elements includes: a mesa including a first semiconductor layer, a light emitting layer, and a second semiconductor layer stacked from top down; and a passivation layer formed on a sidewall surface of the mesa; an insulating layer formed on the top surface of the IC backplane between each of the plurality of micro LED elements; and a Schottky metal layer disposed on the insulating layer and adjacent to the passivation layer of each of the plurality of micro LED elements, wherein the Schottky metal layer creates a depletion region at least in the light emitting layer of each of the plurality of micro LED elements.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a sectional view of an exemplary micro LED element, according to some embodiments of the present disclosure.

FIG. 2 illustrates a structural diagram showing a sectional view of another exemplary micro LED element, according to some embodiments of the present disclosure.

FIG. 3 illustrates a structural diagram showing a sectional view of another exemplary micro LED element, according to some embodiments of the present disclosure.

FIG. 4 illustrates a structural diagram showing a sectional view of another exemplary micro LED element, according to some embodiments of the present disclosure.

FIG. 5 illustrates a structural diagram showing a sectional view of an exemplary micro LED element including a depletion region, according to some embodiments of the present disclosure.

FIG. 6 illustrates a structural diagram showing a sectional view of an exemplary micro LED display panel, according to some embodiments of the present disclosure.

FIG. 7 illustrates a structural diagram showing a top view of an exemplary micro LED display panel, according to some embodiments of the present disclosure.

FIG. 8 illustrates an exemplary display device, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

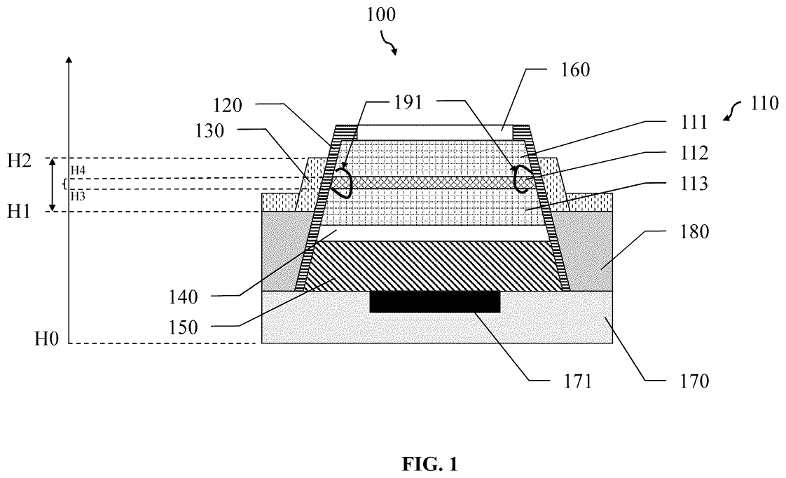

FIG. 1 illustrates a structural diagram showing a sectional view of an exemplary micro LED element 100, according to some embodiments of the present disclosure. Referring to FIG. 1, micro LED element 100 includes a mesa 110, which includes a first semiconductor layer 111, a light emitting layer 112, and a second semiconductor layer 113. First semiconductor layer 111, light emitting layer 112, and second semiconductor layer 113 are stacked from top down to form mesa 110. Micro LED element 100 may also include other components which are omitted here for not obscuring the principle of the present disclosure. As can be seen from FIG. 1, the sidewall of mesa 110 is inclined.

In some embodiments, the diameter of a top surface of mesa 110 is smaller than the diameter of a bottom surface of mesa 110. That is, the sidewall of mesa 110 inclines so that mesa 110 gradually becomes narrower from bottom to top.

The inclined sidewall can be found in other embodiments which will be described below in conjunction with other figures. As mesa 110 can be formed by etching at certain angles, the width of different layers will be different due to the etching mechanism. In an etching process, the upper layers are made narrower than the lower layers. In some embodiments, the diameter of the top surface of the mesa 110 can be similar to, or the same as, the diameter of the bottom surface. That is, the sidewall of mesa can be almost vertical.

Still referring to FIG. 1, mesa 110 further includes a first transparent conductive layer 140. Second semiconductor layer 113 is formed on a top surface of first transparent conductive layer 140. Light emitting layer 112 is formed on second semiconductor layer 113, and first semiconductor layer 111 is formed on light emitting layer 112. Second semiconductor layer 113 can be a P-type epitaxial layer or an N-type epitaxial layer. First semiconductor layer 111 is an N-type epitaxial layer or a P-type epitaxial layer. A material of first semiconductor layer 111 is one or more of GaN, InGaN, AlInGaN, AlGaN, GaP, AlGaInP, or AlInP. Light emitting layer 112 is a quantum well layer. A material of light emitting layer 112 is selected from one or more of InGaN, AlGaN, AlInGaN, InGaP or AlGaInP. First semiconductor layer 111 and second semiconductor layer 113 have opposite conductive types. That is, if first semiconductor layer 111 is a P-type epitaxial layer, then second semiconductor layer 113 is an N-type epitaxial layer; and if first semiconductor layer 111 is an N-type epitaxial layer, then second semiconductor layer 113 is a P-type epitaxial layer. A material of second semiconductor layer 113 is selected from one or more of AlInP, AlGaInP, GaP, GaN, InGaN, AlInGaN or AlGaN.

Micro LED element 100 further includes a passivation layer 120 formed on a sidewall surface of mesa 110. The thickness of passivation layer 120 is in a range of 3 nm to 15 nm, e.g., the thickness of passivation layer 120 can be 3 nm, 4 nm, 5 nm, 6 nm, 7 nm, 8 nm, 9 nm, 10 nm, 11 nm, 12 nm, 13 nm, 14 nm, or 15 nm. In some examples, passivation layer 120 is an ALD (Atomic Layer Deposition)-based layer. A material of passivation layer 120 can be selected from one or more of Al₂O₃, HfN, or SiN. Passivation layer 120 is used as a thin dielectric layer. The introduction of passivation layer 120 may affect the efficiency of a Schottky metal layer 130 described below, however, passivation layer 120 prevents shorting of N-type epitaxial layer and P-type epitaxial layer, and passivates dangling bonds on mesa sidewalls to reduce leakage current in micro LED element 100.

Micro LED element 100 further includes a Schottky metal layer 130 disposed adjacent to passivation layer 120. Schottky metal layer 130 can create a depletion region 191 in at least light emitting layer 112 and, optionally, other layers, as described below. In FIG. 1, depletion region 191 covers an edge of mesa 110 in light emitting layer 112. Depletion region 191 is also created in some part of first semiconductor layer 111 and second semiconductor layer 113. A height of Schottky metal layer 130 spans across at least a part of the height, or thickness, of light emitting layer 112. Referring to FIG. 1, the height of Schottky metal layer 130 extends from H1 to H2, and the height of light emitting layer 112 extends from H3 to H4, where height HO of the bottom surface of micro LED element 100 serves as a reference height. Accordingly, heights H1 to H4 are arbitrarily defined relative to reference height HO of the bottom surface of micro LED element 100. The height of Schottky metal layer 130 extending from H1 to H2 spans across the height of light emitting layer 112 from H3 to H4, such that depletion region 191 created by Schottky metal layer 130 can cover the mesa 110 edge in light emitting layer 112. In other examples, the heights can be defined relative to a different reference height. For example, the heights can instead be defined relative to the bottom surface of second semiconductor layer 113 as an arbitrary reference height. The present disclosure is not limited by the manner in which heights of layer are defined, as long as the heights are measured relative to the same reference height.

In some embodiments of the present disclosure, when A is adjacent to B, it means that a distance between A and B is within a predetermined range. For example, A is close to B, or A can be in direct contact with B.

Furthermore, the height of Schottky metal layer 130 from H1 to H2 can also spans across at least a part of the height of first semiconductor layer 111 and second semiconductor layer 113. This arrangement will enlarge depletion region 191 and ensure the complete coverage of depletion region 191 in light emitting layer 112 at the mesa 110 edge. As a skilled person can understand, Schottky metal can be used to create a depletion region in a semiconductor, which is a nature of the Schottky metal, which is not further described in the present disclosure.

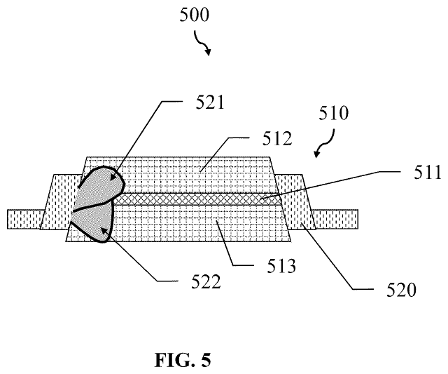

In some examples, Schottky metal layer 130 can be N-type Schottky metal, such that a negative voltage can be optionally applied to the Schottky metal to further deplete electrons in depletion region 191. FIG. 5 illustrates a structural diagram showing a sectional view of an exemplary micro LED element illustrating a depletion region, according to some embodiments of the present disclosure. As shown in FIG. 5, a micro LED element 500 includes a mesa 510. Mesa 510 includes a first semiconductor layer 512, a light emitting layer 511, and a second semiconductor layer 513. In this example, first semiconductor layer 512 is an N-type epitaxial layer and second semiconductor layer 513 is a P-type epitaxial layer. A Schottky metal layer 520 is disposed adjacent to mesa 510. If Schottky metal layer 520 is N-type Schottky metal, a negative voltage can optionally be applied to N-type Schottky metal layer 520. Whether or not a negative voltage is applied, a depletion region 521 created by N-type Schottky metal layer 520 will repel electrons in light emitting layer 511 at least at the mesa 510 edge. Hence, the introduction of depletion region 521 decreases the probability of electrons reaching mesa 110 edge to recombine with holes, which decreases non-radiative recombination. The non-radiative recombination in light emitting layer 511 will decrease significantly, thereby increasing the efficiency of micro LED element 500 and decreasing undesirable thermal affects. When a negative voltage is optionally applied to N-type Schottky metal layer 520, depletion region 521 will be enlarged and biased towards an N-type epitaxial layer, i.e., first semiconductor layer 512, compared with not applying with the negative voltage.

In other examples, Schottky metal layer 130 (FIG. 1) can be a P-type Schottky metal, and a positive voltage can optionally be applied to deplete holes in depletion region 191. For example, referring again to FIG. 5, if Schottky metal layer 520 is a P-type Schottky metal, a positive voltage can optionally be applied to P-type Schottky metal layer 520. Whether or not a positive voltage is applied, a depletion region 522 created by P-type Schottky metal layer 520 will repel holes from light emitting layer 511 at mesa 510 edge. When a positive voltage is optionally applied to P-type Schottky metal layer 520, depletion region 522 will be enlarged and biased towards a P-type epitaxial layer, i.e., second semiconductor layer 513, compared with not applying with the positive voltage.

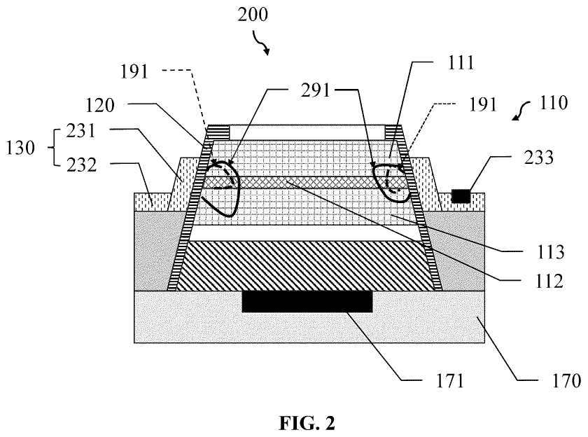

FIG. 2 illustrates a structural diagram showing a sectional view of an exemplary micro LED element 200, according to some embodiments of the present disclosure. Micro LED element 200 in FIG. 2 shares some common components with micro LED element 100 in FIG. 1, and the reference numbers of these components are omitted for simplicity.

As shown in FIG. 2, Schottky metal layer 130 includes a first Schottky part 231 and a second Schottky part 232. First Schottky part 231 and second Schottky part 232 are two connected parts of Schottky metal layer 130. Although differently denoted in FIG. 2, first Schottky part 231 and second Schottky part 232 can be formed in a single process. As can be seen in FIG. 2, first Schottky part 231 is disposed in contact with passivation layer 120 and second Schottky part 232 is disposed to extend from mesa 110. That is, first Schottky part 231 is disposed on an outer surface of passivation layer 120, while second Schottky part 232 is adjacent to passivation layer 120 but does not contact the surface of passivation layer 120. In some embodiments, Schottky metal layer 130 only includes first Schottky part 231 without second Schottky part 232. In this situation, Schottky metal layers 130 of different LED elements 100 can be separated from each other.

Still referring to FIG. 2, micro LED element 200 further includes a bias electrode 233 on second Schottky part 232. As described in conjunction with FIG. 5 above, a negative or positive voltage (also referred to herein as a bias voltage) can optionally be applied to Schottky metal layer 130 via bias electrode 233 for increasing depletion region width. For example, depletion region 191 can be expanded to depletion region 291 by applying a bias voltage to Schottky metal layer 130. The expanded depletion region 291 can further reduce the probability of carriers reaching mesa 110 edge to recombine non-radiatively. Meanwhile, applying a bias voltage to Schottky metal layer 130 may cause additional power consumption by a bias circuit in an integrated circuit (IC) backplane 170, as further described below. It is noted that bias electrode 233 can be part of second Schottky part 232, and a conductive line can be attached thereto. In some embodiments, the bias voltage is in a range of −5V˜+5V.

As described above, when N-type Schottky metal is used, the depletion region 191 (when bias voltage is not applied) induced by Schottky metal layer 130 can repel electrons from mesa 110 edge, especially in light emitting layer 112. Moreover, when biased by a negative voltage, an expanded depletion region 291 is generated with a bias towards an N-type epitaxial layer, i.e., second semiconductor layer 113, and more effectively repel electrons from mesa 110 edge.

As also described above, when P-type Schottky metal is used, depletion region 191 (when bias voltage is not applied) induced by Schottky metal layer 130 can repel holes from mesa 110 edge, especially in light emitting layer 112. Moreover, when biased by a positive voltage, an expanded depletion region 291 is generated with a bias towards the P-type epitaxial layer, i.e., first semiconductor layer 111 (this biasing being not shown in FIG. 2), and more effectively repel holes from mesa 110 edge.

A material of Schottky metal layer 130 can be selected from one or more of W, Au, Ag, Al, Mo, Pd, Ni, Pt, Cr or Ti, in order to form P-type Schottky metal or N-type Schottky metal. In some other embodiments, the material of Schottky metal layer 130 can be any other materials that can be used to create a depletion region.

Referring again to FIG. 1, mesa 110 may include a first transparent conductive layer 140 and a metal reflective layer 150 disposed on a substrate that is also referred to as an IC backplane 170. IC backplane 170 includes a contact pad 171 (e.g., a Cu pad) for electrically connecting IC backplane 170 with metal reflective layer 150.

In some other embodiments, the mesa may include a bottom electrical conductive layer formed on the bottom surface of the second semiconductor layer, and the metal reflective layer can be disposed on a bottom surface of the bottom electrical conductive layer. Moreover, in some embodiments, the bottom electrical conductive layer includes the first transparent conductive layer described above, and the first transparent conductive layer is formed on the bottom surface of the second semiconductor layer. In some embodiments, the bottom electrical conductive layer can be the first transparent conductive layer described above.

As shown in FIG. 1, metal reflective layer 150 is disposed on a top surface of IC backplane 170, and on a bottom surface of first transparent conductive layer 140. To improve light emission efficiency, metal reflective layer 150 is provided to reflect light upwards as viewed in FIG. 1. Metal reflective layer 150 may be made of Ag, Al, etc., and coated with one or more of Cr, Ni, Pt, Ti, or Au.

With further reference to FIG. 1, first transparent conductive layer 140 is formed on a bottom surface of second semiconductor layer 113, and on a top surface of metal reflective layer 150. First transparent conductive layer 140 allows the emitted light by light emitting layer 112 to pass through, meanwhile it electrically connects second semiconductor layer 113 with metal reflective layer 150.

In some embodiments, first transparent conductive layer 140 is provided as a TCO (transparent conductive oxide) layer, for example, an ITO (Indium Tin Oxide) layer, an AZO (Aluminium doped Zinc Oxide) layer, a GZO (Gallium doped Zinc Oxide), an ATO (Antimony doped Tin Oxide) layer, an FTO (Fluorine doped Tin Oxide) layer, or the like.

With further reference to FIG. 1, micro LED element 100 includes an insulating layer 180 formed on IC backplane 170. Insulating layer 180 covers IC backplane 170 and provides insulation to surface components of IC backplane 170. In addition, Schottky metal layer 130 can be deposited on the surface of insulating layer 180.

With further reference to FIG. 1, Micro LED element 100 may further include a second transparent conductive layer 160 formed on a top surface of mesa 110. More particularly, second transparent conductive layer 160 is formed on the top surface of first semiconductor layer 111 and surrounded by passivation layer 120. Second transparent conductive layer 160 can be formed with the same material as first transparent conductive layer 140.

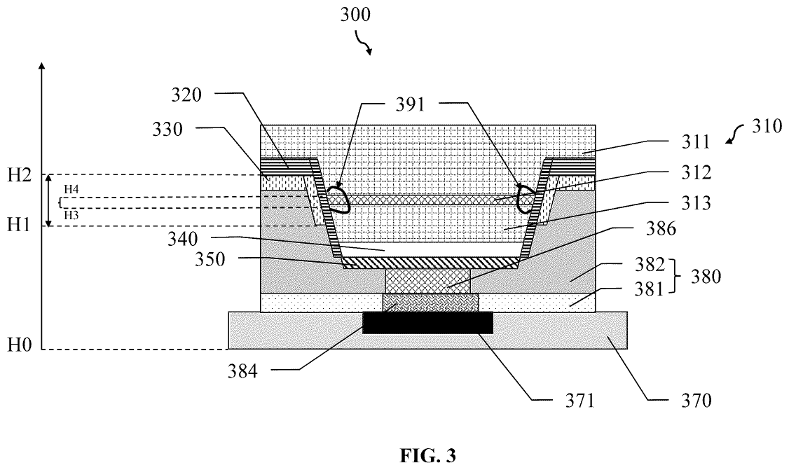

FIG. 3 illustrates a structural diagram showing a sectional view of an exemplary micro LED element 300, according to some embodiments of the present disclosure. Unless otherwise stated or emphasized, the component with the same name or a like reference number here are utilized for the same purpose as those in FIGS. 1 and 2.

Referring to FIG. 3, micro LED element 300 includes a mesa 310, which includes a first semiconductor layer 311, a light emitting layer 312, and a second semiconductor layer 313. First semiconductor layer 311, light emitting layer 312, and second semiconductor layer 313 are stacked from top down to form mesa 310. As can be seen from FIG. 3, the sidewall of mesa 310 is inclined.

In some embodiments, the diameter of a top surface of mesa 310 is greater than the diameter of a bottom surface of mesa 310. That is, the sidewall of mesa 310 inclines so that mesa 310 gradually becomes broader from bottom to top.

As mesa 310 can be formed by etching at certain angles, the width of different layers will be different due to the etching mechanism. In an etching process, mesa 310 can be etched while inverted, the upper layers are etched to be narrower than the lower layers.

Still referring to FIG. 3, mesa 310 further includes a transparent conductive layer 340. Second semiconductor layer 313 is formed on a top surface of transparent conductive layer 340. Light emitting layer 312 is formed on second semiconductor layer 313, and first semiconductor layer 311 is formed on light emitting layer 312. Other aspects of first semiconductor layer 311, light emitting layer 312, and second semiconductor layer 313 are substantially the same as those of first semiconductor layer 111, light emitting layer 112, and second semiconductor layer 113, respectively, described above, and are not further described here.

Micro LED element 300 further includes a passivation layer 320 formed on a sidewall surface of mesa 310. Other aspects of passivation layer 320 are substantially the same as those of passivation layer 120 described above, and are not further described here.

Micro LED element 300 further includes a Schottky metal layer 330 disposed adjacent to passivation layer 320. Schottky metal layer 330 can create a depletion region 391 in light emitting layer 312 and other layers. In FIG. 3, depletion region 391 covers an edge of mesa 310 in light emitting layer 312. Depletion region 391 is also created in some part of first semiconductor layer 311 and second semiconductor layer 313. A height of Schottky metal layer 330 spans across at least a part of the height, or thickness, of light emitting layer 312. Referring to FIG. 3, the height of Schottky metal layer 330 extends from H1 to H2, and the height of light emitting layer 312 extends from H3 to H4, where height HO of the bottom surface of micro LED element 300 serves as a reference height. Accordingly, heights H1 to H4 in FIG. 3 are arbitrarily defined relative to reference height HO of the bottom surface of micro LED element 300. The height of Schottky metal layer 330 extending from H1 to H2 spans across the height of light emitting layer 312 from H3 to H4, such that depletion region 391 created by Schottky metal layer 330 can cover the mesa 310 edge in light emitting layer 312. In other examples, the heights can be defined relative to a different reference height. For example, the heights can instead be defined relative to the bottom surface of second semiconductor layer 313 as an arbitrary reference height. The present disclosure is not limited by the manner in which heights of layer are defined, as long as the heights are measured relative to the same reference height.

Furthermore, the height of Schottky metal layer 330 from H1 to H2 can also span across at least a part of the height of semiconductor layer 311 and second semiconductor layer 313. This arrangement will enlarge depletion region 391 and ensure the complete coverage of depletion region 391 in light emitting layer 312 at the mesa 310 edge.

In some examples, Schottky metal layer 330 can be N-type Schottky metal, such that a negative voltage can be used to deplete electrons in depletion region 391. In other examples, Schottky metal layer 330 can be P-type Schottky metal, such that a positive voltage can be used to deplete holes in depletion region 391.

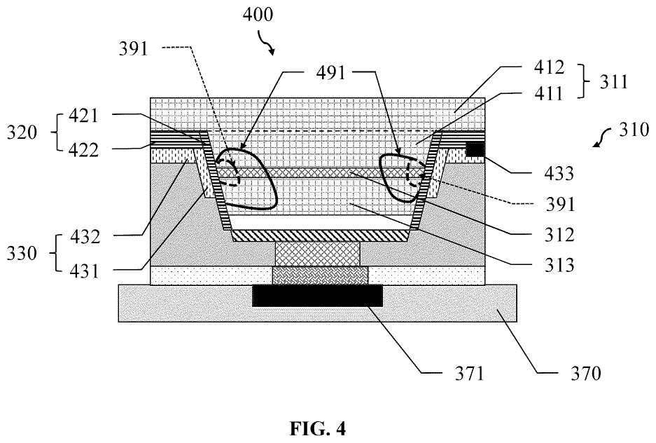

FIG. 4 illustrates a structural diagram showing a sectional view of an exemplary micro LED element 400, according to some embodiments of the present disclosure. Micro LED element 400 in FIG. 4 shares some common components with micro LED element 300 in FIG. 3, and the reference numbers of these components are omitted for simplicity.

Referring to FIG. 4, passivation layer 320 includes a sidewall part 421 and a passivation part 422. Sidewall part 421 is formed on the sidewall surface of mesa 310 and passivation part 422 is formed extending outwards of mesa 310 and is continuously interconnected with a passivation part of adjacent micro LED element. First semiconductor layer 311 further includes a first sub-layer 411 formed on light emitting layer 312, and a second sub-layer 412 formed on first sub-layer 411 and formed on passivation part 422 of passivation layer 320. First sub-layer 411 and second sub-layer 412 can be formed in a single process and may appear to be the same material. As can be appreciated, first sub-layer 411 and second sub-layer 412 are separately described here for explanation of the present disclosure. In some embodiments, first semiconductor layer 311, light emitting layer 312, and second semiconductor layer 313 can be formed in a growing process with different conditions. A part of first semiconductor layer 311 can be etched to form first sub-layer 411 and an un-etched part of first semiconductor layer 311 is formed as second sub-layer 412. Furthermore, in some embodiments, second sub-layers 412 of different LED elements 400 can be interconnected. For example, second sub-layers 412 of different LED elements 400 can be continuously formed, without being broken or interrupted in a whole micro LED array area.

Still referring to FIG. 4, Schottky metal layer 330 includes a first Schottky part 431 and a second Schottky part 432. First Schottky part 431 and second Schottky part 432 are two connected parts of Schottky metal layer 330. Although differently denoted in FIG. 4, first Schottky part 431 and second Schottky part 432 can be formed in a single process. As can be seen in FIG. 4, first Schottky part 431 is disposed in contact with passivation layer 320 and second Schottky part 432 is disposed to extend from mesa 310. As shown in FIG. 4, second Schottky part 432 can be deposited on the bottom surface of passivation part 422.

Still referring to FIG. 4, micro LED element 400 further includes bias electrode 433 on second Schottky part 432. As described in conjunction with FIG. 5 above, a negative or positive voltage (also referred to herein as a bias voltage) can be applied to Schottky metal layer 330 via bias electrode 433 for increasing depletion region width. For example, depletion region 391 can be expanded to a depletion region 491 by applying a bias voltage to Schottky metal layer 330. Expanded depletion region 491 can further reduce the probability of carriers reaching mesa 310 edge to recombine non-radiatively. Meanwhile, applying a bias voltage to Schottky metal layer 330 may cause additional power consumption by a bias circuit in an integrated circuit (IC) backplane 370. It is noted that bias electrode 433 can be part of second Schottky part 432, and a conductive line can be attached thereto to apply a bias voltage. In some embodiments, the bias voltage is in a range of −5V˜+5V.

As described above, when N-type Schottky metal is used, depletion region 391 (when bias voltage is not applied) induced by Schottky metal layer 330 can repel electrons from mesa 310 edge especially in light emitting layer 312. Moreover, when biased by a negative voltage, expanded depletion region 491 is generated with a bias towards an N-type epitaxial layer, i.e., first semiconductor layer 311 (this biasing being not shown in FIG. 4), and more effectively repel electrons from mesa 310 edge.

As also described above, when P-type Schottky metal is used, the depletion region 391 (when bias voltage is not applied) induced by Schottky metal layer 330 can repel holes from mesa 310 edge, especially in light emitting layer 312. Moreover, when biased by a positive voltage, expanded depletion region 491 is generated with a bias towards the P-type epitaxial layer, i.e., second semiconductor layer 313 (as shown in FIG. 4), and more effectively repels holes from mesa 310 edge.

A material of Schottky metal layer 330 can be selected from one or more of W, Au, Ag, Al, Mo, Pd, Ni, Pt, Cr or Ti, in order to form P-type Schottky metal or N-type Schottky metal. In some other embodiments, the material of Schottky metal layer 330 can be any other materials that can be used to create a depletion region.

Referring again to FIG. 3, micro LED element 300 includes an insulating layer 380 formed on an IC backplane 370 and surrounding mesa 310. In some embodiments, insulating layer 380 may further include a first insulating layer 381 formed on IC backplane 370, and a second insulating layer 382 formed surrounding mesa 310. In some embodiments, first insulating layer 381 and second insulating layer 382 are bonded. A contact pad 384 is embedded in first insulating layer 381. A contact pad 386 is embedded in second insulating layer 382 for electrically connecting transparent conductive layer 340, metal reflective layer 350, contact pad 384, and a contact pad 371 in IC backplane 370, such that second semiconductor layer 313 can be electrically connected with IC backplane 370 and controlled thereby. In some other embodiments, insulating layer 380 can be a single layer, and a single contact pad can be embedded in insulating layer 380 to replace contact pads 384 and 386 for the electrical connection purpose as described above.

Metal reflective layer 350 is provided to reflect light upward, as viewed in FIG. 3. Metal reflective layer 350 may be made composed and coated as described above for metal reflective layer 150.

In some embodiments of the present disclosure, although not shown in the figures, a diameter of a top surface of the mesa of a micro LED element can be similar to a diameter of a bottom surface of the mesa. In some embodiments, the diameter of the top surface of the mesa of the micro LED element is the same as the diameter of the bottom surface of the mesa. That is, the sidewall of mesa is almost vertical. In this case, the above structures described in conjunction with FIGS. 1 to 4 can also be adopted here, unless such combination is technically impossible.

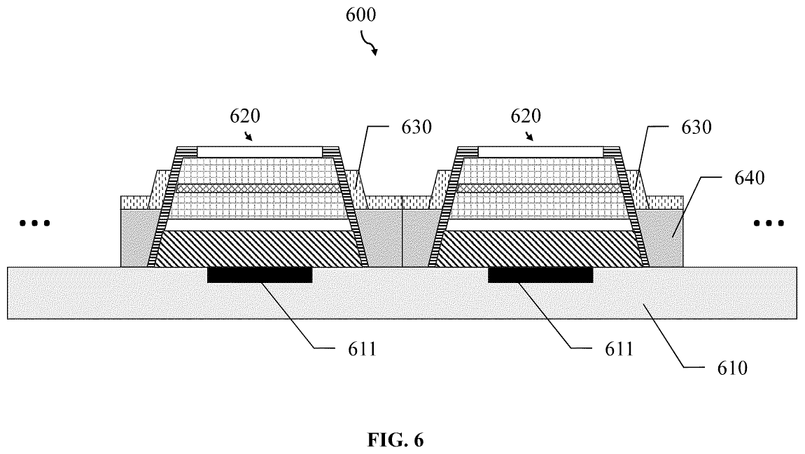

FIG. 6 illustrates a structural diagram showing a sectional view of an exemplary micro LED display panel 600, according to some embodiments of the present disclosure. As shown in FIG. 6, micro LED display panel 600 includes an integrated circuit (IC) backplane 610 (e.g., corresponding to IC backplane 170 in FIG. 1 or 2, or IC backplane 370 in FIG. 3 or 4). A plurality of bottom pads 611 (e.g., corresponding to contact pad 171 in FIG. 1 or 2, or contact pad 371 in FIG. 3 or 4) is embedded in IC backplane 610 such that one bottom pad corresponds to one micro LED element 620.

Micro LED display panel 600 further includes a plurality of micro LED elements 620 (e.g., corresponding to micro LED element 100 in FIG. 1, micro LED element 200 in FIG. 2, micro LED element 300 in FIG. 3, or micro LED element 400 in FIG. 4). Each of the plurality of micro LED elements 620 is disposed on a top surface of IC backplane 610. In the present disclosure, the top surface of the IC backplane is a surface that the IC backplane can be provided as a substrate for arranging components. As can be appreciated, the top surface, or its corresponding bottom surface on the opposite side, is typically larger than other sides of the IC backplane.

A Schottky metal layer 630 (e.g., corresponding to Schottky metal layer 130 in FIG. 1 or 2, or Schottky metal layer 330 in FIG. 3 or 4) of the plurality of micro LED elements 620 is electrically interconnected to the Schottky metal layers 630 of the other micro LED elements 620. In some examples, Schottky metal layer 630 is deposited in a single process, so the deposited layer is contiguous among the plurality of micro LED elements. Moreover, the connected Schottky metal layer 630 is more easily connectable to a bias voltage source. One or more electrodes connected to Schottky metal layer 630 can be sufficient to provide a bias voltage thereto. It can be understood that in FIG. 6, micro LED display panel 600 including two micro LED elements is showing only for illustrative purpose, the structure shown can be extended to form a complete micro LED display panel 600. Micro LED display panel 600 further includes an insulating layer 640 formed on an IC backplane 610 between each of the plurality of micro LED elements 620. Insulating layer 640 covers IC backplane 610 and provides insulation to surface components of IC backplane 610. In addition, Schottky metal layer 630 can be deposited on the surface of insulating layer 640.

Some embodiments of the present disclosure provide a micro LED display panel. The LED display panel includes an integrated circuit (IC) backplane, a plurality of micro LED elements disposed on a top surface of the IC backplane, an insulating layer, and a Schottky metal layer. Each of the plurality of micro LED elements includes a mesa and a passivation layer. The mesa includes a first semiconductor layer, a light emitting layer, and a second semiconductor layer which are stacked from top down. The passivation layer is formed on a sidewall surface of the mesa. The insulating layer is formed on the top surface of the IC backplane between each of the plurality of micro LED elements. The Schottky metal layer is disposed on the insulating layer and adjacent to the passivation layer of each of the plurality of micro LED elements. By such arrangement, the Schottky metal layer creates a depletion region at least in the light emitting layer of each of the plurality of micro LED elements.

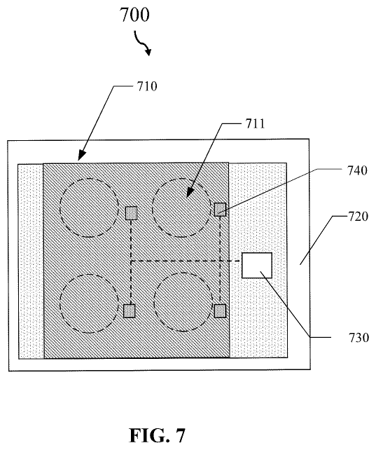

FIG. 7 illustrates a structural diagram showing a top view of a micro LED display panel 700, according to some embodiments of the present disclosure. Referring to FIG. 7, micro LED display panel 700 includes a micro LED array area 710 and an IC (integrated circuit) backplane 720 (e.g., corresponding to IC backplane 170 in FIG. 1 or 2, or IC backplane 370 in FIG. 3 or 4). Micro LED array area 710 is located on IC backplane 720 to form an image display area of micro LED display panel 700. The rest of the area on IC backplane 720 not covered by micro LED array area 710 is formed as a non-functional area. IC backplane 720 is formed at the back surface of micro LED array area 710 with a part extending outside of, i.e., not covered by, micro LED array area 710. Micro LED array area 710 includes a plurality of micro LED elements 711 (e.g., corresponding to micro LED element 100 in FIG. 1, micro LED element 200 in FIG. 2, micro LED element 300 in FIG. 3, or micro LED element 400 in FIG. 4) provided in an array. It can be understood that in FIG. 7, micro LED array area 710 including 2×2 micro LED elements is shown only for illustrative purpose. IC backplane 720 is configured to control the plurality of micro LED elements 711. For example, IC backplane 720 can drive the plurality of micro LED elements 711 to display an image. IC backplane 720 may include a bottom pad array (not shown) corresponding to micro LED array area 710. The bottom pad array includes a plurality of bottom pads (e.g., corresponding to contact pad 171 in FIG. 1 or 2 or contact pad 371 in FIG. 3 or 4) such that one bottom pad corresponds to one micro LED element 711. One micro LED element of the plurality of micro LED elements is electrically connected with one bottom pad of the plurality bottom pads. Each micro LED element 711 may include a bias electrode 740 (e.g., corresponding to bias electrode 233 in FIG. 2, or bias electrode 433 in FIG. 4), such that one bias electrode 740 corresponds to one micro LED element 711. Bias electrodes 740 can be connected to a bias circuit 730 in IC backplane 720 for realizing an expanded depletion region in the light emitting layer of each micro LED element 711. In some other examples, the number of bias electrodes 433 may be less than the number micro LED elements 711 since the Schottky metal layer is contiguous among different micro LED elements in these examples. Hence, one bias electrode may be sufficient to provide bias voltage to the Schottky metal layer. Bias circuit 730 provides a common bias voltage to bias electrodes 740.

Each micro LED element 711 herein has a very small volume. The light emitting area of the micro LED display panel, e.g., micro LED display panel 700 is very small, such as 1 mm×1 mm, 3 mm×5 mm, etc. In some embodiments, the light emitting area of micro LED display panel 700 can be less than or equal to or near 0.15 cm², 0.25 cm², or 1 cm². In some embodiments, the light emitting area is the area of the micro LED array area in the micro LED display panel. Micro LED display panel 700 includes one or more micro LED element 711 that form a pixel array in which the micro LED elements are pixels, such as a 1600×1200, 680×480, or 1920×1080-pixel array. The diameter of each micro LED is in the range of about 200 nm to 2 μm.

Different types of micro LED panels can be provided. For example, the resolution of a display panel can range typically from 8×8 to 3840×2160. Common display resolutions include QVGA (Quarter Video Graphics Array) with 320×240 resolution and an aspect ratio of 4:3, XGA (Extended Graphics Array) with 1024×768 resolution and an aspect ratio of 4:3, D (Definition) with 1280×720 resolution and an aspect ratio of 16:9, FHD (Full High Definition) with 1920×1080 resolution and an aspect ratio of 16:9, UHD (Ultra High Definition) with 3840×2160 resolution and an aspect ratio of 16:9, and 4K with 4096×2160 resolution. There can also be a wide variety of pixel sizes, ranging from sub-micron and below to 10 mm and above. The size of the overall display region can also vary widely, ranging from diagonals as small as tens of microns or less up to hundreds of inches or more.

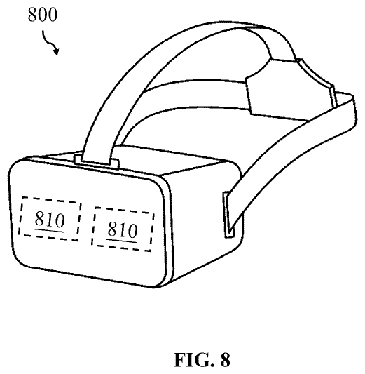

FIG. 8 illustrates an exemplary display device, according to some embodiments of the present disclosure. As shown in FIG. 8, a head-mounted virtual reality device 800 includes two micro LED panels 810 (e.g., corresponding to micro LED display panel 600 in FIG. 6, or micro LED display panel 700 in FIG. 7). Although not shown, head-mounted virtual reality device 800 may also include a central processing unit (CPU), a graphic processing unit (GPU) acting as a signal source, and other related circuitries. The introduction of micro LED panels that embody the micro LED elements described above in head-mounted virtual reality device 800 will improve the lighting efficiency therein, hence reducing energy consumption and improving imaging quality.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments.

Accordingly, although specific terms are employed, they are used in a generic and descriptive sense only and not for purposes of limitation.

What is claimed is:

1. A micro LED element, comprising:
a mesa comprising a first semiconductor layer, a light emitting layer, and a second semiconductor layer stacked from top down;
a passivation layer formed on a sidewall surface of the mesa; and
a Schottky metal layer disposed adjacent to the passivation layer, wherein the Schottky metal layer creates a depletion region at least in the light emitting layer.

2. The micro LED element according to claim 1, wherein a height of the Schottky metal layer spans across at least a part of a height of the light emitting layer.

3. The micro LED element according to claim 2, wherein the height of the Schottky metal layer further spans across at least a part of a height of the first semiconductor layer and/or the second semiconductor layer.

4. The micro LED element according to claim 1, wherein the Schottky metal layer comprises:
a first Schottky part in contact with the passivation layer; and
a second Schottky part extending from the mesa, wherein the second Schottky part is connected to the first Schottky part.

5. The micro LED element according to claim 4, further comprising a bias electrode on the second Schottky part.

6. The micro LED element according to claim 1, wherein a thickness of the passivation layer is in a range of 3 nm to 15 nm.

7. The micro LED element according to claim 1, wherein the passivation layer is an ALD (Atomic Layer Deposition)-based layer.

8. The micro LED element according to claim 1, wherein a material of the Schottky metal layer is selected from one or more of W, Au, Ag, Al, Mu, Ni, Pt, Cr or Ti.

9. The micro LED element according to claim 1, wherein the mesa further comprises a bottom electrical conductive layer formed on a bottom surface of the second semiconductor layer.

10. The micro LED element according to claim 9, wherein the mesa further comprises a metal reflective layer disposed on a bottom surface of the bottom electrical conductive layer.

11. The micro LED element according to claim 9, wherein the bottom electrical conductive layer further comprises a first transparent conductive layer formed on a bottom surface of the second semiconductor layer.

12. The micro LED element according to claim 11, wherein the mesa further comprises a metal reflective layer disposed on a bottom surface of the first transparent conductive layer.

13. The micro LED element according to claim 1, wherein a diameter of a top surface of the mesa is smaller than a diameter of a bottom surface of the mesa.

14. The micro LED element according to claim 13, further comprising a second transparent conductive layer formed on a top surface of the mesa.

15. The micro LED element according to claim 4, wherein a diameter of a top surface of the mesa is greater than a diameter of a bottom surface of the mesa.

16. The micro LED element according to claim 15, wherein the passivation layer comprises a sidewall part and a passivation part, wherein the sidewall part is formed on the sidewall surface of the mesa, and the passivation part is formed extending outwards of the mesa and continuously interconnected with a passivation part of adjacent micro LED element.

17. The micro LED element according to claim 16, wherein the first semiconductor layer comprises a first sub-layer formed on the light emitting layer and a second sub-layer formed on the first sub-layer and covering the passivation part of the passivation layer.

18. The micro LED element according to claim 17, wherein a second Schottky part is deposited on the bottom surface of the passivation part.

19. The micro LED element according to claim 1, wherein a diameter of a top surface of the mesa is similar to a diameter of a bottom surface of the mesa.

20. A micro LED display panel, comprising:
an integrated circuit (IC) backplane; and
a plurality of micro LED elements, each of the plurality of micro LED elements comprising:
a mesa comprising a first semiconductor layer, a light emitting layer, and a second semiconductor layer stacked from top down;
a passivation layer formed on a sidewall surface of the mesa; and
a Schottky metal layer disposed adjacent to the passivation layer, wherein the Schottky metal layer creates a depletion region at least in the light emitting layer,
wherein each of the plurality of micro LED elements is disposed on a top surface of the IC backplane.

21. The micro LED display panel according to claim 20, wherein the Schottky metal layers of each of the plurality of micro LED elements are electrically interconnected.

22. The micro LED display panel according to claim 20, wherein the Schottky metal layers of each of the plurality of micro LED elements are separated from each other.

23. The micro LED display panel according to claim 20, wherein each of the plurality of micro LED elements further comprises a second transparent conductive layer formed on a top surface of the mesa, and the second transparent conductive layers of each of the plurality of micro LED elements are electrically interconnected.

24. The micro LED display panel according to claim 20, wherein each of the plurality of micro LED elements further comprises a second transparent conductive layer formed on a top surface of the mesa, and the second transparent conductive layers of each of the plurality of micro LED elements are separate from each other.

25. A micro LED display panel, comprising:
an integrated circuit (IC) backplane;
a plurality of micro LED elements disposed on a top surface of the IC backplane, wherein each of the plurality of micro LED elements comprises:
a mesa comprising a first semiconductor layer, a light emitting layer, and a second semiconductor layer stacked from top down; and
a passivation layer formed on a sidewall surface of the mesa;
an insulating layer formed on the top surface of the IC backplane between each of the plurality of micro LED elements; and
a Schottky metal layer disposed on the insulating layer and adjacent to the passivation layer of each of the plurality of micro LED elements, wherein the Schottky metal layer creates a depletion region at least in the light emitting layer of each of the plurality of micro LED elements.

26. The micro LED display panel according to claim 25, wherein each of the plurality of micro LED elements further comprises a second transparent conductive layer formed on a top surface of the mesa, and the second transparent conductive layers of each of the plurality of micro LED elements are electrically interconnected.

27. The micro LED display panel according to claim 25, wherein each of the plurality of micro LED elements further comprises a second transparent conductive layer formed on a top surface of the mesa, and the second transparent conductive layers of each of the plurality of micro LED elements are separated from each other.

28. A display device comprising a micro LED display panel, the micro LED display panel comprising:
an integrated circuit (IC) backplane; and
a plurality of micro LED elements, each of the plurality of micro LED elements comprising:
a mesa comprising a first semiconductor layer, a light emitting layer, and a second semiconductor layer stacked from top down;
a passivation layer formed on a sidewall surface of the mesa; and
a Schottky metal layer disposed adjacent to the passivation layer, wherein the Schottky metal layer creates a depletion region at least in the light emitting layer,
wherein each of the plurality of micro LED elements is disposed on a top surface of the IC backplane.
